(19) United States
(12) Patent Application Publication
(10) Pub. No.: US 2026/0231372 A1
(43) Pub. Date: Aug. 6, 2026

(54) ADJUSTABLE MODULAR HEAT SINK

(71) Applicant: Aivres Systems Inc., San Jose, CA (US)

(72) Inventor: Chia-Yuan Nien, TaiChung (TW)

(21) Appl. No.: 19/047,226

(22) Filed: Feb. 6, 2025

(51) Int. Cl. H05K 7/20; G06F 1/20

(52) U.S. Cl. CPC H05K 7/2039; G06F 1/206; H05K 7/20336

(57) ABSTRACT

Disclosed herein is an adjustable heat sink comprising a base, a heat pipe, a first plurality of fixed fins, and a second plurality of sliding fins. The base is adapted to be thermally coupled to a heat-generating electronic component. The heat pipe comprises an evaporator portion and a condenser portion, wherein the evaporator portion is attached to the base, and the condenser portion extends away from the evaporator portion. The first plurality of fixed fins is attached to the condenser portion. At least one fixed fin has two parallel grooves along two opposite sides of the fixed fin, and at least one sliding fin has two parallel edges that are slidably inserted into the two parallel grooves, wherein the fixed fin and the sliding fin overlap at least partially.

### TECHNICAL FIELD

This disclosure is generally related to an adjustable heat sink for use with heat-generating electronic components.

### BACKGROUND

Heat sinks dissipate heat from heat-generating electronic components such as semiconductor chips. Heat from a semiconductor chip is conducted to a heatsink via a thermal interface material, and the heat sink dissipates the heat to surrounding air due to a temperature difference between the heat sink and the air. The thermal dissipation performance of a heat sink may be improved by optimizing the material of the heat sink, by using heat pipes that improves heat conduction from the semiconductor chip to the heatsink, and by optimizing the geometric design of the heatsink so as to increase its surface area for heating dissipation.

Heat sinks are limited by the space available within a computer chassis. As the power consumption of CPUs increase, the thermal dissipation performance of heatsinks must also increase accordingly, and one effective method to achieve higher thermal dissipation performance is to increase the surface area for heat dissipation by utilizing larger fins. Currently, the fins of a CPU's heatsink are often so large that they block access to memory modules (DIMM) that are situated on both sides of the CPU. Maintenance of a computer's memory modules, therefore, require disassembly of the heatsink of the CPU, which must also be reinstalled afterwards. Consequently, such repeated disassembly and reinstallation of the CPU heatsink may inadvertently damage the CPU, which is an expensive component.

The adjustable heat sink disclosed herein have fins that may be adjusted by users. When the fins are fully contracted, the heat sink is less bulky and does not block maintenance access to neighboring components (such as DIMM modules), and when the fins are fully extended, heat sink has more surface area for effective heat dissipation.

### SUMMARY

Described herein is an adjustable heat sink.

In one general aspect, disclosed herein is an adjustable heat sink comprising a base, a heat pipe, a first plurality of fixed fins, and a second plurality of sliding fins. In some embodiments, the base is adapted to be thermally coupled to a heat-generating electronic component. In some embodiments, the heat pipe comprises an evaporator portion and a condenser portion, and the evaporator portion is attached to the base, and the condenser portion extends away from the evaporator portion. In some embodiments, the first plurality of fixed fins is attached to the condenser portion. In some embodiments, at least one fixed fin has two parallel grooves along two opposite sides of the fixed fin, and at least one sliding fin has two parallel edges that are slidably inserted into the two parallel grooves. In some embodiments, the fixed fin and the sliding fin overlap at least partially.

In some embodiments, the base comprises a substantially flat region adapted for interfacing with the heat-generating electronic component. In some embodiments, the heat-generating electronic component is a CPU, a GPU, or a coprocessor.

In some embodiments, the condenser portion of the heat pipe extends away from the evaporator portion in a substantially vertical direction.

In some embodiments, each of the first plurality of fixed fins is a substantially flat metal sheet and contains a hole, and the first plurality of fixed fins are stacked in parallel with substantially equal spacing. In some embodiments, the condenser portion of the heat pipe is inserted through the hole of each of the first plurality of fixed fins. In some embodiments, the hole has a collar around an edge of the hole that protrudes away from the substantially flat metal sheet.

In some embodiments, the least one fixed fin is a substantially flat metal sheet, and the two parallel grooves are folded or rolled edges of the substantially flat metal sheet.

In some embodiments, the at least one sliding fin is a substantially flat metal sheet and contains a slit that is elongated along a direction of the two parallel edges.

In some embodiments, each of the second plurality of sliding fins is a substantially flat metal sheet and contains a slit, and the second plurality of sliding fins are stacked in parallel with substantially equal spacing. In some embodiments, the condenser portion of the heat pipe is inserted through the slit of each of the second plurality of sliding fins. In some embodiments, the slit has a collar around an edge of the slit that protrudes away from the substantially flat metal sheet.

In some embodiments, an area of overlap between the at least one sliding fin and the at least one fixed fin changes with a sliding movement of the at least one sliding fin in the two parallel grooves.

In another general aspect, disclosed herein is a heat sink comprising a base, a plurality of pairs of cooling fins, and a heat pipe. In some embodiments, the base comprises a substantially flat region adapted for interfacing with a heat-generating electronic component. In some embodiments, each pair of cooling fins comprises a sliding fin and a corresponding fixed fin. In some embodiments, the sliding fin comprises a first metal sheet that is substantially flat and having two parallel edges, and a slit in the first metal sheet. In some embodiments, the corresponding fixed fin comprises a second metal sheet that is substantially flat, a hole in the second metal sheet, and two parallel grooves along two opposite sides of the second metal sheet. In some embodiments, the two parallel edges of the sliding fin are slidably inserted into the two parallel grooves of the corresponding fixed fin, and an area of overlap between the sliding fin and the corresponding fixed fin changes with a sliding movement of the sliding fin relative to the corresponding fixed fin. The heat pipe may comprise an evaporator portion and a condenser portion. In some embodiments, the evaporator portion is attached to the base, and the condenser portion extends away from the evaporator portion and going through the slit of the sliding fin and the hole of the corresponding fixed fin in each one of the plurality of pairs of cooling fins. In some embodiments, the corresponding fixed fin of each one of the plurality of pairs of cooling fins is attached to the condenser portion of the heat pipe.

In some embodiments, the sliding fin further comprises a first collar around the slit that protrudes away from the first metal sheet, and the corresponding fixed fin further comprises a second collar around the hole that protrudes away from the second metal sheet.

In some embodiments, the two parallel grooves in the corresponding fixed fin are folded or rolled edges of the second metal sheet.

In some embodiments, the slit of the sliding fin is elongated in a direction of the sliding movement of the sliding fin relative to the corresponding fixed fin.

In yet another general aspect, disclosed herein is a computer system comprising a chassis, a printed circuit board disposed in the chassis and having a heat-generating electronic component, and a heat sink attached to the heat-generating electronic component. In some embodiments, the heat sink comprises a base, a plurality of pairs of cooling fins, and a heat pipe. In some embodiments, the base comprises a substantially flat region that is thermally connected with the heat-generating electronic component. In some embodiments, each pair of cooling fins comprises a sliding fin and a corresponding fixed fin. In some embodiments, the sliding fin comprises a first metal sheet that is substantially flat and having two parallel edges, and a slit in the first metal sheet. In some embodiments, the corresponding fixed fin comprises a second metal sheet that is substantially flat, a hole in the second metal sheet, and two parallel grooves along two opposite sides of the second metal sheet. In some embodiments, the two parallel edges of the sliding fin are slidably inserted into the two parallel grooves of the corresponding fixed fin, and an area of overlap between the sliding fin and the corresponding fixed fin changes with a sliding movement of the sliding fin relative to the corresponding fixed fin. In some embodiments, the heat pipe is thermally connected to the base and extends away from the base and going through the slit of the sliding fin and the hole of the corresponding fixed fin in each one of the plurality of pairs of cooling fins. In some embodiments, the corresponding fixed fin of each pair of cooling fins is thermally connected to the heat pipe.

In some embodiments, the heat-generating electronic component is a CPU, a GPU, or a coprocessor.

In some embodiments, when the area of overlap between the sliding fin and the corresponding fixed fin is at its maximum, a projected area of the plurality of pairs of cooling fins on the printed circuit board is substantially within an area that the base occupies on the printed circuit board.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings:

FIG. 1 shows an adjustable heat sink.

FIGS. 2, 2A, 2B, and 2C show detailed features of a fixed fin and a sliding fin.

FIGS. 3, 3A, and 3B illustrate the sliding movements of the sliding fins.

FIGS. 4, 4A, and 4B show a side view of the sliding movements of the sliding fins.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The term “substantially” is used herein to mean approximately, in the region of, roughly, or around.

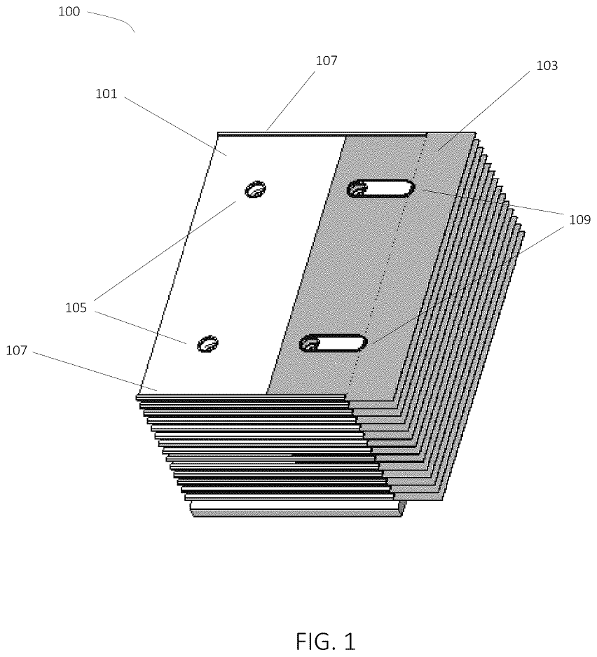

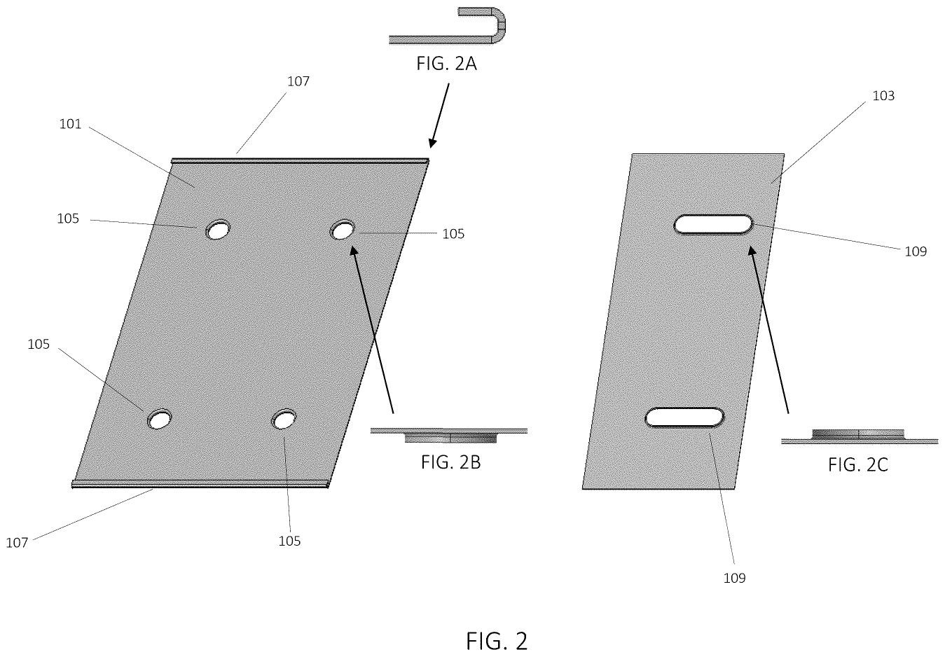

The embodiments will now be explained with the accompanying figures. Reference is first made to FIGS. 1 and 2, which show an adjustable heat sink 100. FIGS. 1 and 2 shows a modular heat sink 100 comprising a set of fixed fins 101 and a set of sliding fins 103. Each fix fin 101 is a rectangular flat metal sheet and contains four round holes 105 (two of which are obscured from view in FIG. 1). Each fix fin 101 also has two grooves 107 that are parallel to each other and are situated along two opposite sides of the fixed fin 101. Each sliding fin 103 is also flat rectangular metal sheet and contains two slits 109 that look like elongated holes. The fixed fins and the sliding fins have the same width. The sliding fin 103 is slidably inserted into the two parallel grooves 107 of the fixed fin 101.

FIGS. 2A and 2B show the details of a fixed fin 101. As shown in FIG. 2A, the grooves along two parallel sides of the fixed fin 101 are formed by folding or rolling the edges of the metal sheet. As shown in FIG. 2B, each hole 105 has a collar around an edge of the hole that protrudes away from the plane of the metal sheet. Similarly, each slit 109 also has a collar around an edge of the slit that protrudes away from the plane of the metal sheet as shown in FIG. 2C.

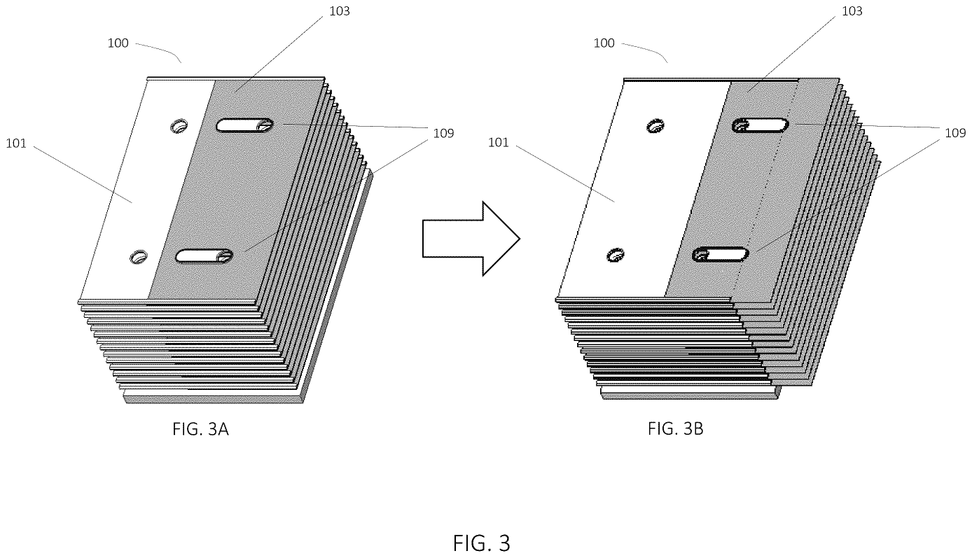

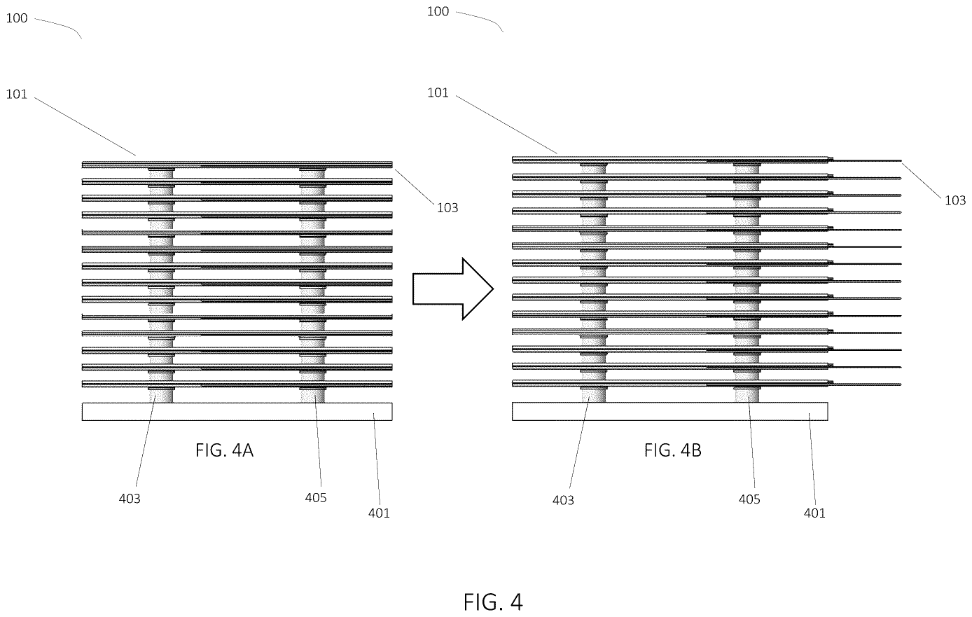

FIGS. 3A and 3B show the movement of the sliding fins. In FIG. 3A, the adjustable heat sink 100 has all of its sliding fins 103 pushed inwards, such that the area of overlap between each sliding fin 103 and its corresponding fixed fin 101 is maximized. When each sliding fin 103 is pull out fully, as shown in FIG. 3B, the area of overlap between each sliding fin 103 and its corresponding fixed fin 101 is minimized. The extent of the movement of each sliding fin 103 is limited by the length of the slits 109 and the heat pipes that go through the slits, which is explained below in FIG. 4.

FIGS. 4A and 4B show the movement of the sliding fins from a slide view. The adjustable heat sink 100 comprises multiple fixed fins 101 and sliding fins 103, and each fixed fin 101 is paired with a sliding fin 103. Heat pipes 403 and 405 are connected to these cooling fins. Specifically, one or more heat pipes 403 are connected to the fixed fins 101 through the holes on each fixed fin. In addition, one or more heat pipes 405 are connected to the fixed fins 101 through the holes on each fixed fin, and are also connected to the sliding fins 103 through the slits of each sliding fin. A heat pipes usually has an evaporator portion and a condenser portion. Here the condenser portion (bottom end) of the heat pipes 403 and 405 are connected to a base 401, and the evaporator portion (upper part) of the heat pipes 403 and 405 are connected to the cooling fins.

The base can be of any shape suitable to be attached to a heat-generating electronic component, such as, for example, an electronic component mounted to a printed circuit board (not shown). A heat-generating electronic component is any device that produces heat that is undesirable; most typically, the electronic component is a central processing unit (CPU) or a graphics processing unit (GPU), for example. The base is integral, i.e., formed as a continuous body of material that has a high propensity for conducting heat although the base may be formed in multiple attached pieces, i.e., non-integral.

The base can be formed from materials such as aluminum, copper, and/or other metal alloys, plastic and/or epoxy, and/or any other suitable heat conducting material. In one embodiment, the base is formed from a continuous piece of aluminum alloy and its bottom is shaped to fit the contour of one or more electronic components. In another embodiment, the base is formed from two different materials, such as for example, aluminum in a first region and copper in a second region. The two regions are attached together by a conventional means such as bolting or gluing with heat-conductive adhesive.

A heat pipe is a vacuum-sealed pipe that is filled with a heat-transfer liquid, such as water, and has the interior wall of the heat pipe covered with a wicking material. As the electronic component heats up, the evaporator end (or the “hot end”) of the heat pipe closest to the electronic component also heats up. The liquid near the hot end of the heat pipe eventually evaporates and the resultant vapor collects at the condenser end (or the “cool end”) of the heat pipe where the vapor then condenses. The condensed liquid flows back to the hot end of the heat pipe via wicking, and evaporating liquid again migrates to the cool end of the heat pipe. This evaporation/condensation cycle repeats as the heat pipe transfers heat efficiently such that the hot end of the heat pipe is kept at or near the same temperature as the cool end. Furthermore, because the boiling point of the fluid changes with the pressure, the pressure inside the heat pipe can be reduced such that boiling occurs at a desired temperature. In some embodiments, the heat pipe is straight. In some embodiments, the heat pipe is bent or curved. In some embodiments, the heat pipe has a serpentine shape at an evaporator end in order to increase thermal contact with the electronic component. In some embodiments, the heat pipe has a U-shape, with one evaporator end in the middle and two condenser ends on the sides. In some embodiments, the heat pipe is a loop.

In some embodiments, the base is attached to a single heat pipe. In some embodiments, the base is attached to multiple heat pipes. In the embodiment shown in FIGS. 1 to 4, four heat pipes are attached to the base 401. The heat pipe can be attached to the base in any manner, including adhesive, form-fitted (“snap-on”), harnessed, bolted, etc. In some embodiments, the evaporator end of the heat pipe is attached to the base, and the condenser end of the heat pipe extends away from the evaporator end in a substantially vertical direction. In some embodiments, the evaporator end of the heat pipe is attached to the base, and the condenser end of the heat pipe extends away from the base in a substantially perpendicular direction. In some embodiments, the condenser end of the heat pipe extends away from the base in an inclined angle that is between 0 and 90 degrees.

The adjustable heat sink includes fixed fins and sliding fins, which are intended to increase the surface area in order to promote convective heat dissipation to ambient air. By increasing the surface area in contact with the ambient air, heat is more effectively dissipated from the electronic component through the heat sink to the ambient air.

The fins can be attached to one or more heat pipes in a variety of manners. They are typically machined to form fit around the heat pipes, such that friction holds the fins in place and flange spacers are used to maintain space between the fins when assembled. Alternatively, the fins can be attached in other manners, such as by using adhesive or harnessing. In some embodiments the fins may be detachable from the heat sink.

In some embodiments, the adjustable heat sink comprises multiple sliding fins for each fixed fin. In some embodiments, for example, two sliding fins slide out from a fixed in two opposite directions.

In some embodiments, one set of fins slides relative another set of fixed fins. In some embodiments, one set of fins rotates relative to another set of fixed fins. In some embodiments, the adjustable heat sink according to the present disclosure comprises sliding fins that move in a linear direction in order to adjust the heat sink's surface area available for heat dissipation, as may be required for optimal cooling performance under a variety of circumstances. In some embodiments, the adjustable heat sink comprises fins that move in a sliding, rotating, or tilting manner in order to adjust the heat sink's surface area for heat dissipation. In some embodiments, the adjustable heat sink comprises fins that are capable of sliding, rotating, or tilting motion, or any combination thereof.

In some embodiments, the movement of the sliding fins are guided by parallel grooves present in the fixed fins. In some embodiments, instead of, or in addition to, the parallel grooves, the movement of the sliding fins are guided by rails, spring clips, protrusions, notches, indentations, recesses, and/or other mechanical limiters, which both guide and limit the movement of the sliding fins. These mechanical limiters provide positional limits to the sliding fins, ensure stable and smooth movement when the sliding fins are being adjusted, and prevent their inadvertent or accidental movement.

In some embodiments, the adjustable heat sink further comprises structure elements that connect the sliding fins such that all of them can moved together. In some embodiments, for examples, the sliding fins are connected together by rods, threads, or wires.

In some embodiments, the adjustable heat sink employs vapor chambers in place of the heat pipes described above.

The adjustable heat sinks according to the present disclosure do not incur significant extra manufacturing cost over conventional heat sinks. The parallel grooves along the edges of fixed fins limit the movement of the sliding fins to only one dimension (i.e., the direction of sliding movement). The extent of movement of the sliding fins is limited by the length of the slits and the heat pipes that go though the slits.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A heat sink comprising:
a base adapted to be thermally coupled to a heat-generating electronic component;
a heat pipe comprising an evaporator portion and a condenser portion, wherein the evaporator portion is attached to the base, and the condenser portion extends away from the evaporator portion;
a first plurality of fixed fins attached to the condenser portion, wherein at least one fixed fin has two parallel grooves along two opposite sides of the at least one fixed fin; and
a second plurality of sliding fins, wherein at least one sliding fin has two parallel edges that are slidably inserted into the two parallel grooves, wherein the at least one sliding fin at least partially overlaps with the at least one fixed fin.

2. The heat sink of claim 1, wherein the base comprises a substantially flat region adapted for interfacing with the heat-generating electronic component.

3. The heat sink of claim 2, wherein the heat-generating electronic component is a CPU, a GPU, or a coprocessor.

4. The heat sink of claim 1, wherein the condenser portion of the heat pipe extends away from the evaporator portion in a substantially vertical direction.

5. The heat sink of claim 1, wherein each of the first plurality of fixed fins is a substantially flat metal sheet and contains a hole, and the first plurality of fixed fins are stacked in parallel with substantially equal spacing.

6. The heat sink of claim 5, wherein the condenser portion of the heat pipe is inserted through the hole of each of the first plurality of fixed fins.

7. The heat sink of claim 5, wherein the hole has a collar around an edge of the hole that protrudes away from the substantially flat metal sheet.

8. The heat sink of claim 1, wherein the least one fixed fin is a substantially flat metal sheet, and the two parallel grooves are folded or rolled edges of the substantially flat metal sheet.

9. The heat sink of claim 1, wherein the at least one sliding fin is a substantially flat metal sheet and contains a slit that is elongated along a direction of the two parallel edges.

10. The heat sink of claim 1, wherein each of the second plurality of sliding fins is a substantially flat metal sheet and contains a slit, and the second plurality of sliding fins are stacked in parallel with substantially equal spacing.

11. The heat sink of claim 10, wherein the condenser portion of the heat pipe is inserted through the slit of each of the second plurality of sliding fins.

12. The heat sink of claim 10, wherein the slit has a collar around an edge of the slit that protrudes away from the substantially flat metal sheet.

13. The heat sink of claim 1, wherein an area of overlap between the at least one sliding fin and the at least one fixed fin changes with a sliding movement of the at least one sliding fin in the two parallel grooves.

14. A heat sink comprising a base, a plurality of pairs of cooling fins, and a heat pipe;
wherein:
the base comprises a substantially flat region adapted for interfacing with a heat-generating electronic component;
each pair of cooling fins comprises a sliding fin and a corresponding fixed fin; and
the sliding fin comprises a first metal sheet that is substantially flat and having two parallel edges, and a slit in the first metal sheet;
the corresponding fixed fin comprises a second metal sheet that is substantially flat, a hole in the second metal sheet, and two parallel grooves along two opposite sides of the second metal sheet;
the two parallel edges of the sliding fin are slidably inserted into the two parallel grooves of the corresponding fixed fin, and an area of overlap between the sliding fin and the corresponding fixed fin changes with a sliding movement of the sliding fin relative to the corresponding fixed fin;
the heat pipe comprising an evaporator portion and a condenser portion;
the evaporator portion is attached to the base, and the condenser portion extends away from the evaporator portion and going through the slit of the sliding fin and the hole of the corresponding fixed fin in each one of the plurality of pairs of cooling fins; and
the corresponding fixed fin of each one of the plurality of pairs of cooling fins is attached to the condenser portion of the heat pipe.

15. The heat sink of claim 14, wherein the sliding fin further comprises a first collar around the slit that protrudes away from the first metal sheet, and the corresponding fixed fin further comprises a second collar around the hole that protrudes away from the second metal sheet.

16. The heat sink of claim 14, wherein the two parallel grooves in the corresponding fixed fin are folded or rolled edges of the second metal sheet.

17. The heat sink of claim 14, wherein the slit of the sliding fin is elongated in a direction of the sliding movement of the sliding fin relative to the corresponding fixed fin.

18. A computer system comprising:
a chassis,
a printed circuit board disposed in the chassis and having a heat-generating electronic component, and
a heat sink attached to the heat-generating electronic component;
wherein:
the heat sink comprises a base, a plurality of pairs of cooling fins, and a heat pipe;
the base comprises a substantially flat region that is thermally connected with the heat-generating electronic component;
each pair of cooling fins comprises a sliding fin and a corresponding fixed fin; and
the sliding fin comprises a first metal sheet that is substantially flat and having two parallel edges, and a slit in the first metal sheet;
the corresponding fixed fin comprises a second metal sheet that is substantially flat, a hole in the second metal sheet, and two parallel grooves along two opposite sides of the second metal sheet;
the two parallel edges of the sliding fin are slidably inserted into the two parallel grooves of the corresponding fixed fin, and an area of overlap between the sliding fin and the corresponding fixed fin changes with a sliding movement of the sliding fin relative to the corresponding fixed fin;
the heat pipe is thermally connected to the base and extends away from the base and going through the slit of the sliding fin and the hole of the corresponding fixed fin in each one of the plurality of pairs of cooling fins; and
the corresponding fixed fin of each pair of cooling fins is thermally connected to the heat pipe.

19. The computer system of claim 18, wherein the heat-generating electronic component is a CPU, a GPU, or a coprocessor.

20. The computer system of claim 18, wherein when the area of overlap between the sliding fin and the corresponding fixed fin is at its maximum, an projected area of the plurality of pairs of cooling fins on the printed circuit board is substantially within an area that the base occupies on the printed circuit board.
